(19) United States
(12) Patent Application Publication
(10) Pub. No.: US 2026/0009129 A1
(43) Pub. Date: Jan. 8, 2026

(54) GAS SUPPLY, PROCESSING APPARATUS, GAS SUPPLY METHOD, AND METHOD OF MANUFACTURING SEMICONDUCTOR DEVICE

(71) Applicant: Kokusai Electric Corporation, Tokyo (JP)

(72) Inventors: Yusaku OKAJIMA, Toyama-shi (JP); Mika URUSHIHARA, Toyama-shi (JP); Taketoshi MORIYA, Toyama-shi (JP)

(73) Assignee: Kokusai Electric Corporation, Tokyo (JP)

(21) Appl. No.: 19/248,816

(22) Filed: Jun. 25, 2025

(30) Foreign Application Priority Data
Jul. 8, 2024 (JP) 2024-109894

(51) Int. Cl. C23C 16/455

(52) U.S. Cl. CPC C23C 16/45506

(57) ABSTRACT

A gas supply includes: a flow path in which a gas flows; a plurality of openings respectively provided in a direction intersecting the flow path to supply the gas into a processing chamber, and a flow modifier provided to block a portion of the flow path, and configured to perturb flow of the gas flowing in the flow path toward the plurality of openings.

### CROSS-REFERENCE TO RELATED APPLICATION

This application is based upon and claims the benefit of priority from Japanese Patent Application No. 2024-109894, filed on Jul. 8, 2024, the entire contents of which are incorporated herein by reference.

### TECHNICAL FIELD

The present disclosure relates to a gas supply, a processing apparatus, a gas supply method, and a method of manufacturing a semiconductor device.

### BACKGROUND

In a related art, as one step of steps of manufacturing a semiconductor device, a processing of forming a film on a substrate may be performed. According to the related art, an opening that jets a gas is provided in a nozzle, thereby supplying a processing gas to evenly flow on the substrate. However, when a flow rate of the processing gas, which is required along with refinement and complication of a substrate surface, is increased, it may be difficult to make gas evenly flow between substrates.

### SUMMARY

Some embodiments of the present disclosure provide a technique capable of making gas evenly flow between substrates.

According to one embodiment of the present disclosure, there is provided a gas supply comprising: a flow path in which a gas flows; a plurality of openings respectively provided in a direction intersecting the flow path to supply the gas into a processing chamber; and a flow modifier provided to block a portion of the flow path, and configured to perturb flow of the gas flowing in the flow path toward the plurality of openings.

### BRIEF DESCRIPTION OF DRAWINGS

The accompanying drawings, which are incorporated in and constitute a part of the specification, illustrate embodiments of the present disclosure.

FIG. 1 is a schematic configuration view of a substrate processing apparatus used in one aspect of the present disclosure.

FIG. 2 is a cross-sectional view taken along line A-A of FIG. 1.

FIG. 3 is a schematic configuration view of a controller of the substrate processing apparatus used in the one aspect of the present disclosure, in which a control system of the controller is illustrated as a block diagram.

FIG. 4 is a flowchart illustrating a film forming sequence in the one aspect of the present disclosure.

FIG. 5A is a longitudinal cross-sectional view of a nozzle of the one aspect of the present disclosure.

FIG. 5B is an enlarged cross-sectional view of a portion indicated by arrow B in FIG. 5A.

FIG. 5C is a side view of the nozzle of the one aspect of the present disclosure.

FIG. 6 is a longitudinal cross-sectional view of a nozzle of a comparative example.

FIG. 7A is a longitudinal cross-sectional view of a nozzle of another aspect of the present disclosure.

FIG. 7B is a top view of the nozzle of FIG. 7A.

FIG. 8 is a side view of a nozzle of still another aspect of the present disclosure.

FIG. 9A is a view illustrating a film thickness distribution when a nozzle of embodiment 1 is used.

FIG. 9B is a view illustrating a film thickness distribution when a nozzle of embodiment 2 is used.

FIG. 9C is a view illustrating a film thickness distribution when a nozzle of a comparative example is used.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### <One Aspect of Present Disclosure>

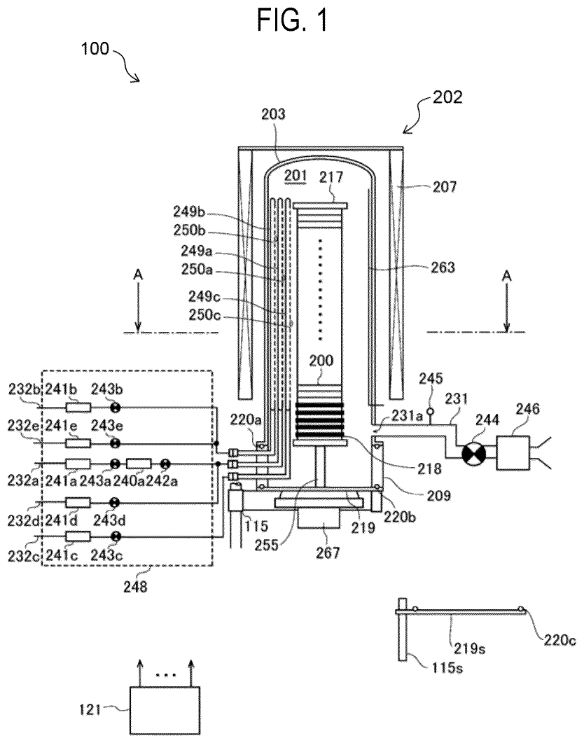

One aspect of the present disclosure is described below mainly with reference to FIGS. 1 to 6. In addition, the drawings used in the following description are all schematic, and a dimensional relationship between respective elements, a ratio between the respective elements, and the like, illustrated in the drawings, do not necessarily coincide with actual ones. Further, between a plurality of drawings, the dimensional relationship between the respective elements, the ratio between the respective elements, and the like do not necessarily coincide with each other.

### (1) Configuration of Substrate Processing Apparatus

As illustrated in FIG. 1, a substrate processing apparatus 100 as a processing apparatus includes a processing furnace 202. The processing furnace 202 includes a heater 207 as a temperature adjuster. The heater 207 has a cylindrical shape and is supported by a holding plate to be vertically installed. The heater 207 also functions as an activation mechanism (exciter) that thermally activates (excites) a gas.

Inside the heater 207, a reaction tube 203 is disposed concentrically with the heater 207. The reaction tube 203 is made of, for example, a heat-resistant material such as quartz (SiO₂) or silicon carbide (SiC), and is formed in a cylindrical shape with an upper end closed and a lower end opened. Below the reaction tube 203, a manifold 209 is disposed concentrically with the reaction tube 203. The manifold 209 is made of, for example, a metal material such as stainless steel (SUS), and is formed in a cylindrical shape with upper and lower ends opened. The upper end of the manifold 209 engages with a lower end of the reaction tube 203 to be configured to support the reaction tube 203. An O-ring 220a as a seal member is provided between the manifold 209 and the reaction tube 203. The reaction tube 203 is vertically installed similarly to the heater 207. A processing container (reaction container) is mainly configured by the reaction tube 203 and the manifold 209. A processing chamber 201 is formed in a cylinder hollow portion of the processing container. The processing chamber 201 is configured to be capable of accommodating a wafer 200 as a substrate which is a workpiece. A processing on the wafer 200 is performed in the processing chamber 201.

In the processing chamber 201, nozzles 249a to 249c as gas supplies (also referred to as gas suppliers, or gas feeders) are individually provided to penetrate through a sidewall of the manifold 209. The nozzles 249a to 249c are also referred to as first to third nozzles, respectively. The nozzles 249a to 249c are made of, for example, a heat-resistant material such as quartz or SiC. Gas supply pipes 232a to 232c are connected to the nozzles 249a to 249c, respectively. The nozzles 249a to 249c are nozzles different from one another. Each of the nozzles 249a and 249c is provided adjacent to the nozzle 249b. Further, details of the nozzles 249a to 249c will be described later.

In the gas supply pipe 232a, a mass flow controller (MFC) 241a as a flow rate controller, a valve 243a as an opening/closing valve, a storage (storage container) 240a as a raw material container that is capable of storing a gas, and a valve 242a as an opening/closing valve are provided sequentially from an upstream side of a gas flow.

A gas supply pipe 232d is connected to a downstream side of the gas supply pipe 232a. In the gas supply pipe 232d, an MFC 241d and a valve 243d are provided sequentially from the upstream side of the gas flow. The gas supply pipes 232a and 232d and the storage 240a may be made of, for example, a metal material such as SUS.

The storage 240a is configured as a gas tank with a gas capacity larger than that of an ordinary pipe. By opening/closing the valve 243a at an upstream side from the storage 240a and the valve 242a at a downstream side from the storage 240a, it is possible to perform charge of a gas supplied from the gas supply pipe 232a in the storage 240a or supply of the gas charged in the storage 240a to the processing chamber 201.

By closing the valve 242a and opening the valve 243a, it is possible to charge a gas with a flow rate adjusted by the MFC 241a in the storage 240a. When a predetermined amount of gas is charged in the storage 240a such that a pressure in the storage 240a reaches a predetermined pressure, by closing the valve 243a and opening the valve 242a, it is possible to supply (flash supply) at a time (in a short time) a high-pressure gas charged in the storage 240a to the processing chamber 201 via the gas supply pipe 232a and the nozzle 249a. Further, in the flash supply, the valve 243a may be opened.

In the gas supply pipes 232b and 232c, MFCs 241b and 241c and valves 243b and 243c as opening/closing valves are provided sequentially from the upstream side of the gas flow, respectively. A gas supply pipe 232e is connected to the gas supply pipe 232b at a downstream side of the valve 243b of the gas supply pipe 232b. In the gas supply pipe 232e, an MFC 241e and a valve 243e are provided sequentially from the upstream side of the gas flow. The gas supply pipes 232b, 241c and 232e is made of, for example, a metal material such as SUS.

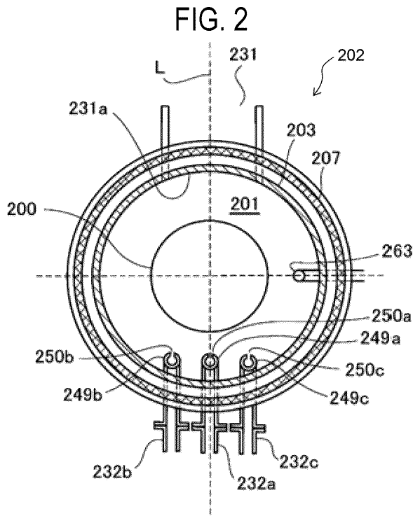

As illustrated in FIG. 2, the nozzles 249a to 249c are provided in an annular space in plan view between an inner wall of the reaction tube 203 and the wafer 200 so as to extend upward in an arrangement direction of the wafers 200 along the inner wall of the reaction tube 203 from a lower portion to an upper portion. That is, the nozzles 249a to 249c are provided along a wafer arrangement region in which the wafers 200 are arranged, in a region horizontally surrounding the wafer arrangement region, on a lateral side of the wafer arrangement region. In plan view, the nozzle 249a is arranged so as to be opposed to an exhaust port 231a to be described later on a straight line across a center of the wafer 200 loaded in the processing chamber 201. The nozzles 249b and 249c are arranged so as to interpose a straight line L passing through the nozzle 249a and a center of the exhaust port 231a between both sides along the inner wall of the reaction tube 203 (outer peripheral portion of the wafer 200). The straight line L is also a straight line passing through the nozzle 249a and the center of the wafer 200. That is, it can also be said that the nozzle 249c is provided as a side opposite to the nozzle 249b across the straight line L. The nozzles 249b and 249c are arranged in line symmetry with the straight line L as a symmetry axis. In side surfaces of the nozzles 249a to 249c, gas supply holes 250a to 250c through which a gas is supplied are provided, respectively. Each of the gas supply holes 250a to 250c is opened so as to be opposed to (face) the exhaust port 231a in plan view, so that it is possible to supply the gas toward the wafer 200. A plurality of gas supply holes 250a to 250c are provided from the lower portion to the upper portion of the reaction tube 203.

From the gas supply pipe 232a, a raw material gas is supplied into the processing chamber 201 via the MFC 241a, the valve 243a, the storage 240a, the valve 242a, and the nozzle 249a.

From the gas supply pipe 232b, a reaction gas is supplied into the processing chamber 201 via the MFC 241b, the valve 243b, and the nozzle 249b. Further, the reaction gas is a material having a molecular structure (chemical structure) different from that of the raw material gas.

From the gas supply pipes 232d and 232e, an inert gas is supplied into the processing chamber 201 via the MFCs 241d and 241e, the valves 243d and 243e, the gas supply pipes 232a and 232b, and the nozzles 249a and 249b, respectively. Further, from the gas supply pipe 232c, the inert gas is supplied into the processing chamber 201 via the MFC 241c, the valve 243c, and the nozzle 249c. The inert gas acts as a purge gas, a carrier gas, a dilution gas, or the like.

Mainly, a raw material gas supply system (raw material gas supply line) is configured by the gas supply pipe 232a, the MFC 241a, the valves 243a and 242a, and the storage 240a. Mainly, a reaction gas supply system (reaction gas supply line) is configured by the gas supply pipe 232b, the MFC 241b, and the valve 243b. Mainly, an inert gas supply system (inert gas supply line) is configured by the gas supply pipes 232c to 232e, the MFCs 241c to 241e, and the valves 243c to 243e.

In addition, each or both of the raw material gas and the reaction gas are referred to as a film forming gas, and each or both of the raw material gas supply system and the reaction gas supply system are referred to as a film forming gas supply system (film forming gas supply line).

Any one or all of the various gas supply systems described above may be configured as an integrated gas supply system 248 in which the valves 243a, 242a, and 243b to 243e, the storage 240a, the MFCs 241a to 241e, and the like are integrated. The integrated gas supply system 248 is configured such that opening/closing operations of the valves 243a, 242a, and 243b to 243e, flow rate adjustment operations by the MFCs 241a to 241e, or the like are controlled by a controller 121 which will be described later.

In a lower portion of a sidewall of the reaction tube 203, the exhaust port 231a that exhausts an atmosphere in the processing chamber 201 is provided. An exhaust pipe 231 is connected to the exhaust port 231a. The exhaust pipe 231 is made of, for example, a metal material such as SUS. A vacuum pump 246 as a vacuum exhaust device is connected to the exhaust pipe 231 via a pressure sensor 245 as a pressure detector (pressure detection part) that detects a pressure in the processing chamber 201 and an auto pressure controller (APC) valve 244 as a pressure regulator (pressure regulation part). The APC valve 244 is configured to be able to vacuum-exhaust the processing chamber 201 and stop the vacuum-exhaust by opening and closing a valve thereof in a state in which the vacuum pump 246 is operated, and regulate the pressure in the processing chamber 201 by adjusting a valve opening degree, based on pressure information detected by the pressure sensor 245, in a state in which the vacuum pump 246 is operated. Mainly, an exhaust system is configured by the exhaust pipe 231, the APC valve 244, and the pressure sensor 245. The vacuum pump 246 may be included in the exhaust system.

Below the manifold 209, a seal cap 219 is provided as a cover body capable of airtightly closing a lower end opening of the manifold 209. The seal cap 219 is made of, for example, a metal material such as SUS and is formed in a disk shape. An O-ring 220b as a seal member that comes in contact with a lower end of the manifold 209 is provided on an upper surface of the seal cap 219. Below the seal cap 219, a rotary mechanism 267 that rotates a boat 217 to be described later is disposed. A rotary shaft 255 of the rotary mechanism 267 is made of, for example a metal material such as SUS and is connected to the boat 217 by penetrating through the seal cap 219. The rotary mechanism 267 is configured to rotate the boat 217, thereby rotating the wafer 200. The seal cap 219 is configured to be raised and lowered in a vertical direction by a boat elevator 115 as a lifting mechanism disposed outside the reaction tube 203.

The boat elevator 115 is configured as a transfer device (transfer mechanism) that raises and lowers the seal cap 219, thereby loading and unloading (transferring) the wafer 200 into/from the processing chamber 201.

A shutter 219s that is capable of airtightly closing the lower end opening of the manifold 209 in a state in which the boat 217 is unloaded from the processing chamber 201 by lowering the seal cap 219 is provided below the manifold 209. The shutter 219s is made of, for example, a metal material such as SUS and is formed in a disk shape. An O-ring 220c as a seal member that comes in contact with the lower end of the manifold 209 is provided on an upper surface of the shutter 219s. An opening/closing operation (a lifting operation, a turning operation, or the like) of the shutter 219s is controlled by a shutter opening/closing mechanism 115s.

The boat 217 as a substrate support is configured to support a plurality of, for example, 25 to 200 wafers 200 horizontally, in multiple stages so as to be aligned in the vertical direction with centers aligned with one another, i.e., to be arranged at intervals. Heat insulating plates 218 made of, for example, a heat-resistant material such as quartz and SiC are supported in multiple stages in a lower portion of the boat 217.

In the reaction tube 203, a temperature sensor 263 as a temperature detector is provided. By adjusting a degree of supplying electric power to the heater 207, based on temperature information detected by the temperature sensor 263, the inside of the processing chamber 201 has a desired temperature distribution. The temperature sensor 263 is provided along the inner wall of the reaction tube 203.

[Nozzle 249a]

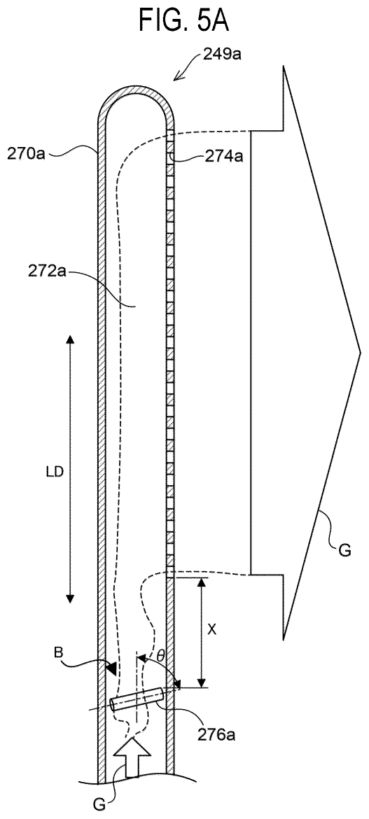

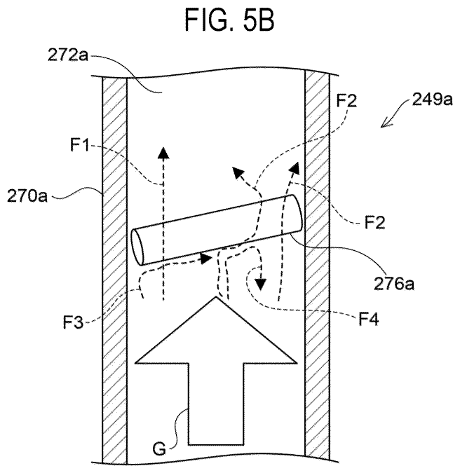

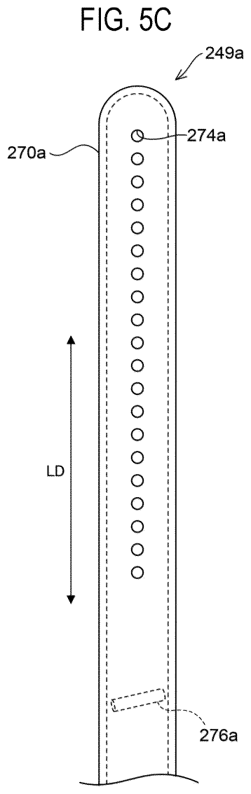

Details of a nozzle 249a are described with reference to FIGS. 1, 5A, and 5C. Further, the nozzle 249a of this embodiment has the same configuration except a kind of gas flowing therein and a modifier 276a which will be described later. Here, the nozzles 249b and 249c may have the same configuration as the nozzle 249a.

As illustrated in FIG. 1, the nozzle 249a of this embodiment penetrates through the sidewall of the manifold 209 and is bent in the middle to extend upwardly. Hereinafter, a portion that extends upwardly from a bent portion of the nozzle 249a is referred to as a straight tube portion 270a. Further, the straight tube portion 270a of this embodiment extends along an up/down direction (also referred to as a vertical direction).

As illustrated in FIG. 5A, the nozzle 249a includes a flow path 272a, a first opening 274a as an opening, and a modifier 276a as a flow modifier. Further, the first opening 274a is abbreviated as an “opening 274a.”

The flow path 272a is a hollow portion provided inside the nozzle 249a. In the flow path 272a, a gas introduced from the gas supply pipe 232a flows.

The opening 274a is a jet hole of the gas, which is provided in the nozzle 249a so as to supply the gas from the nozzle 249a into the processing chamber 201. As illustrated in FIG. 5A, a plurality of openings 274a are each provided in a direction intersecting the flow path 272a. Specifically, as illustrated in FIGS. 5A and 5C, in the straight tube portion 270a of the nozzle 249a, the plurality of openings 274a are provided in a column at intervals in a length direction LD of the straight tube portion 270a (also referred to as an axial direction of the straight tube portion 270a). The plurality of openings 274a are configured by through-holes that penetrate through the straight tube portion 270a in a direction intersecting the length direction LD of the straight tube portion 270a, which is a direction in which the flow path 272a extends. Further, in this embodiment, the plurality of openings 274a are each configured by a through-hole that penetrates the straight tube portion 270a in a thickness direction of a sidewall of the straight tube portion 270a. The thickness direction of the sidewall of the straight tube portion 270a is a direction orthogonal to the length direction LD of the straight tube portion 270a.

A shape (opening shape) of the opening 274a is, for example, at least one of a circle, an ellipse, and a polygon. Further, in this embodiment, as illustrated in FIG. 5C, the shape of the opening 274a is a circle. The polygon as the shape of the opening 274a includes a triangle, a quadrangle, a rhombus, a trapezoid, and the like.

As illustrated in FIG. 5A, the modifier 276a is a portion of the nozzle 249a, which is provided in the straight tube portion 270a to block a portion of the flow path 272a and is configured to perturb flow of the gas flowing in the flow path 272a toward the plurality of openings 274a.

The modifier 276a is provided at an upstream side from the plurality of openings 274a in a supply direction of the gas in the flow path 272a. Further, the supply direction of the gas in the flow path 272a is a direction in which the gas flows in the flow path 272a, and is indicated by arrow G in the drawing.

The modifier 276a is provided at a position distant at a predetermined distance X from the opening 274a located at a most upstream side in the supply direction of the gas among the plurality of openings 274a.

Further, modifier 276a is configured to generate flow of a plurality of gases in the flow path 272a. Specifically, the modifier 276a may be configured to change at least a partial flow of the gas from uniform flow to turbulent flow or may be configured to change at least a partial flow velocity of the gas flowing in the flow path 272a.

Further, the modifier 276a may be configured to make at least a flow of the gas face the inner wall (inner surface of the sidewall) of the straight tube portion 270a, which constitutes the flow path 272a and has the opening 274a provided therein.

Further, the modifier 276a may be configured to generate turbulent flow of the gas in a vicinity of the plurality of openings 274a.

A shape of the modifier 276a may be a rod shape, a plate shape, a spherical shape, a net shape, a honeycomb shape, or a combined shape thereof. In this embodiment, as illustrated in FIG. 5A, the shape of the modifier 276a is a round bar. However, the present disclosure is not limited to this configuration, and a cross-sectional shape of the modifier 276a may be at least one of a circle, an ellipse, and a polygon when the shape of the modifier 276a is a rod shape, a plate shape, or a spherical shape.

In addition, as illustrated in FIG. 5B, a plurality of flows of the gas may be generated in the flow path 272a according to the shape of the modifier 276a. Further, as the modifier 276a is disposed obliquely with respect to the length direction of the straight tube portion 270a, a plurality of flows of the gas may be generated in the flow path 272a. Further, according to arrangement of the modifier 276a on a cross-section of the straight tube portion 270a, a plurality of flows of the gas may be generated in the flow path 272a. That is, by adjusting the shape of the modifier 276a, a slope θ of the modifier 276a with respect to the length direction of the straight tube portion 270a, and the arrangement of the modifier 276a on the cross-section of the straight tube portion 270a, a plurality of flows of the gas may be generated in the flow path 272a.

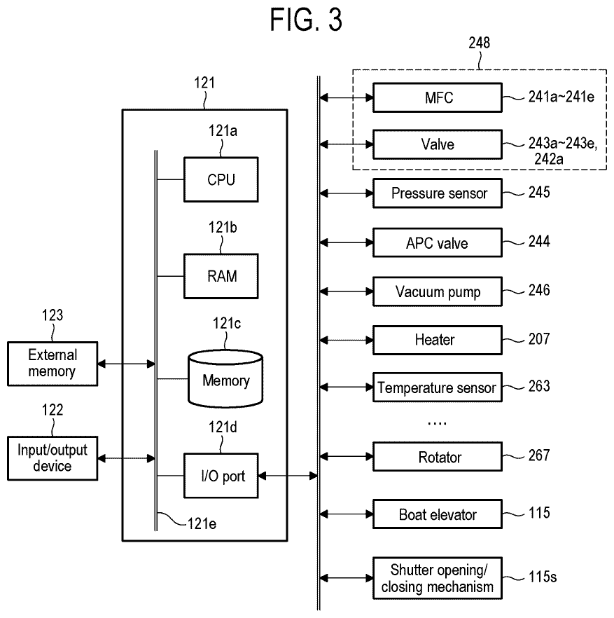

As illustrated in FIG. 3, a controller 121 as a controller (control means) is configured as a computer including a central processing unit (CPU) 121a, a random access memory (RAM) 121b, a storage device 121c, and an I/O port 121d. The RAM 121b, the storage device 121c, and the I/O port 121d are configured to be able to exchange data with the CPU 121a via an internal bus 121e. An input/output device 122 configured as, for example, a touch panel or the like is connected to the controller 121.

The storage device 121c includes, for example, a flash memory, a hard disk drive (HDD), a solid state drive (SSD), and the like. In the storage device 121c, a control program that controls operations of the substrate processing apparatus 100, a process recipe in which procedures, conditions and the like of a substrate processing to be described later are described, and the like are readably stored. The process recipe is a combination that allows the controller 121 to allow the substrate processing apparatus to execute each procedure in the substrate processing to be described later to obtain a predetermined result, and functions as a program. Hereinafter, the process recipe, the control program, and the like are collectively and simply referred to as a program. Further, the process recipe is simply referred to as a recipe. In a case where the term “program” is used in this specification, this may include a case where only the recipe alone is included, a case where only the control program alone is included, or a case where both the recipe and the control program are included. The RAM 121b is configured as a memory area (work area) in which programs, data, and the like, read by the CPU 121a, are temporarily stored.

The I/O port 121d is connected to the MFCs 241a to 241e, the valves 243a, 242a, and 243b to 243e, the pressure sensor 245, the APC valve 244, the vacuum pump 246, the temperature sensor 263, the heater 207, the rotary mechanism 267, the boat elevator 115, the shutter opening/closing mechanism 115s, and the like, which are described above.

The CPU 121a is configured to be capable of reading and executing the control program from the storage device 121c, and reading the recipe from the storage device 121c in response to an input and the like of an operation command from the input/output device 122. The CPU 121a is configured to be capable of controlling, in accordance with a content of the read recipe, a flow rate adjustment operation of various gases by the MFCs 241a to 241e, an opening/closing operation of the valves 243a and 242a and the values 243b to 243e, a pressure regulating operation by the APC valve 244, based on an opening/closing operation of the APC valve 244 and the pressure sensor 245, start and stop of the vacuum pump 246, a temperature adjustment operation of the heater 207, based on the temperature sensor 263, a rotation and rotation speed adjustment operation of the boat 217 by the rotary mechanism 267, a lifting operation of the boat 217 by the boat elevator 115, an opening/closing operation of the shutter 219s by the shutter opening/closing mechanism 115s, and the like.

The controller 121 may be configured by installing the above-described program stored in an external storage device 123 into the computer. Examples of the external storage device 123 include, for example, a magnetic disk such as an HDD, an optical disk such as a CD, a magneto-optical disk such as an MO, a semiconductor memory such as a USB memory or an SSD, and the like. The storage device 121c and the external storage device 123 are configured as computer-readable recording media. Hereinafter, the storage device 121c and the external storage device 123 are collectively and simply referred to as recording media. In a case where the term “recording medium” is used in this specification, this may include a case where only the storage device 121c alone is included, a case where only the external storage device 123 alone is included, or a case where both of the storage device 121c and the external storage device 123 are included. Further, the program may be provided to the computer by using a communication means such as the Internet and a dedicated line without using the external storage device 123.

### (2) Substrate Processing Process

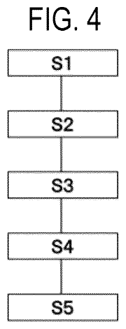

As one step of steps of manufacturing a semiconductor device, using the above-described substrate processing apparatus 100, an example of a sequence of performing a processing on the wafer 200 as the substrate, i.e., a film forming sequence of forming a film on the wafer 200 is described mainly with reference to FIG. 4. In the following description, operations of respective parts constituting the substrate processing apparatus 100 may be controlled by the controller 121.

In the film forming sequence of this aspect, by performing, a predetermined number of times (n times, n is an integer of 1 or more), a cycle including step A of supplying the raw material gas from the raw material gas supply line into the processing chamber 201 in which the wafer 200 is accommodated and step B of supplying the reaction gas into the processing chamber 201 in which the wafer 200 is accommodated, a film is formed on the wafer 200.

In the film forming sequence of this aspect, when the step A and the step B are alternately performed n times (n is an integer of 1 or more), it is preferable to interpose a step of purging the processing chamber 201 between the step A and the step B. Here, the term “purge” means removing the raw material gas or an intermediate, which exists in the processing chamber 201 due to supply of the inert gas into the processing chamber 201. The term “exhaust” means removing the raw material or the intermediate, which exists in the processing chamber 201 without supplying the inert gas into the processing chamber 201.

A case where the term “wafer” is used in this specification may mean the wafer itself or a stacked body of the wafer and a predetermined layer or film formed on a surface thereof. A case where the term “surface of the wafer” is used in this specification may mean the surface of the wafer itself or a surface of a predetermined layer or the like, which is formed on the wafer. A case where the term “forming a predetermined layer on the wafer” is described in this specification may mean forming the predetermined layer directly on the surface of the wafer itself or forming the predetermined layer on a layer or the like, which is formed on the wafer. A case where the term “substrate” is used in this specification has the same meaning as the case where the term “wafer” is used.

### (Substrate Load S1: Wafer Charge and Boat Load)

After a plurality of wafers 200 are loaded on the boat 217 (wafer charge), the shutter 219s is moved by the shutter opening/closing mechanism 115s, and the lower end opening of the manifold 209 is opened (shutter open). Thereafter, as illustrated in FIG. 1, the boat 217 that supports the plurality of wafers 200 is raised by the boat elevator 115 and is loaded into the processing chamber 201 (boat load). In this state, the seal cap 219 seals the lower end of the manifold 209 via the O-ring 220b.

### (Preprocessing S2: Pressure Regulation and Temperature Adjustment)

After the boat load is finished, the inside of the processing chamber 201, i.e., a space in which the wafer 200 exists is vacuum-exhausted (depressurization-exhausted) by the vacuum pump 246 so as to achieve a desired pressure (vacuum degree). At that time, the pressure in the processing chamber 201 is measured by the pressure sensor 245, and the APC valve 244 is feedback-controlled based on information of the measured pressure (pressure regulation). Further, the wafer 200 in the processing chamber 201 is heated by the heater 207 such that a temperature of the wafer 200 in the processing chamber 201 reaches a desired processing temperature. At that time, the degree of supplying electric power to the heater 207 is feedback-controlled based on the temperature information detected by the temperature sensor 263, such that the inside of the processing chamber 201 has a desired temperature distribution (temperature adjustment). Further, rotation of the wafer 200 by the rotary mechanism 267 is started. The exhaust in the processing chamber 201, the heating and rotation of the wafer 200 are all continuously performed at least until the processing on the wafer 200 is finished.

### (Substrate Processing S3: Film Forming Processing)

Thereafter, the following steps A and B are sequentially performed.

### [Step A]

In this step, the raw material gas is supplied to the wafer 200 in the processing chamber 201. Specifically, by closing the valve 242a and opening the valve 243a, the raw material gas flows into the gas supply pipe 232a. The raw material gas is flow rate-adjusted by the MFC 241a to be supplied into the storage 240a. Accordingly, the raw material gas is charged in the storage 240a. When a predetermined amount of the raw material gas is charged in the storage 240a, the valve 243a is closed to maintain a state in which the raw material gas is charged in the storage 240a.

Subsequently, in this step, by opening the valve 242a, the high-pressure raw material gas charged in the storage 240a flows into the processing chamber 201 at a time. Accordingly, the raw material gas is supplied at a time to the wafer 200 (flash supply of the raw material gas). In the flash supply, the raw material gas is jetted from the nozzle 249a by a difference between the pressure in the storage 240a and the pressure in the processing chamber 201. At this time, the valve 243a is opened. Here, by opening the valves 243c to 243e, the inert gas may be supplied into the processing chamber 201 via the respective valves 249a to 249c. In addition, this step is preferably performed in a state in which the exhaust system is substantially completely closed (the APC valve 244 is substantially completely closed). Here, the term “substantially closed (substantially completely closed)” includes a state in which the APC valve 244 is opened by about 0.1% to about a few % or a state in which because of performance of the APC valve 244, exhaust to the exhaust system is made even when the APC valve 244 is controlled to be closed by 100%.

Subsequently, in this step, by closing the valves 243a and 242a, the supply of the raw material gas into the processing chamber 201 is stopped. Further, the inside of the processing chamber 201 is vacuum-exhausted, for example, by completely opening the APC valve 244, so that a gas remaining in the processing chamber 201 and the like are removed from the processing chamber 201.

### [Step B]

After the step A is finished, the reaction gas is supplied to a first layer formed on the wafer 200 in the processing chamber 201, i.e., the wafer 200.

Specifically, by opening the valve 243b, the reaction gas flows into the gas supply pipe 232b. The reaction gas is flow rate-adjusted by the MFC 241b to be supplied into processing chamber 201 via the nozzle 249b and exhausted from the exhaust port 231a. At this time, the reaction gas is supplied to the wafer 200 (reaction gas supply). At this time, by opening the valves 243c to 243e, the inert gas may be supplied into the processing chamber 201 via the respective nozzles 249a to 249c.

By supplying the reaction gas, at least a portion of the first layer formed on the wafer 200 is modified. As a result, a second layer is formed on an uppermost surface of the wafer 200 as a base.

After the second layer is formed, the valve 243b is closed to stop the supply of the reaction gas into the processing chamber 201. Further, by the same processing sequence as the purge in the step A, a gas remaining in the processing chamber 201 and the like are removed from the processing chamber 201 (purge).

### [Predetermined Number of Times of Performance]

By performing the above-described cycle including the steps A and B a predetermined number of times (n times, n is an integer of 1 or more), it is possible to form a film a surface of the wafer 200. The above-described cycle is preferably repeated a plurality of times. That is, it is preferable that the above-described cycle is repeated a plurality of times until a thickness of the film reaches a desired thickness.

### (Post-Processing S4: After-Purge and Atmospheric Pressure Restoration)

After the formation of the film with the desired thickness on the wafer 200 is finished, the inert gas as the purge gas is supplied from each of the nozzles 249a to 249c into the processing chamber 201 and is discharged from the exhaust port 231a. Accordingly, the inside of the processing chamber 201 is purged, and a gas, a reaction by-product, and the like, which remain in the processing chamber 201, are removed from the processing chamber 201 (after-purge). Thereafter, the atmosphere in the processing chamber 201 is replaced with the inert gas (inert gas replacement), and the pressure in the processing chamber 201 is restored to a normal pressure (atmospheric pressure restoration).

### (Substrate Unload S5: Boat Unload and Wafer Discharge)

Thereafter, the seal cap 219 is lowered by the boat elevator 115, and the lower end of the manifold 209 is opened. Then, the processed wafer 200 is unloaded from the lower end of the manifold 209 to the outside of the reaction tube 203 in a state of being supported by the boat 217 (boat unload). After the boat unload, the shutter 219s is moved, and the lower end opening of the manifold 209 is sealed by the shutter 219s via the O-ring 220c (shutter close). The processed wafer 200 is unloaded to the outside of the reaction tube 203 and then taken out from the boat 217 (wafer discharge).

(3) Change in Flow of Gas by Flow Modifier of this Aspect

Next, a change in flow of the gas flowing in the flow path according to this aspect is described with reference to FIGS. 5A and 5B.

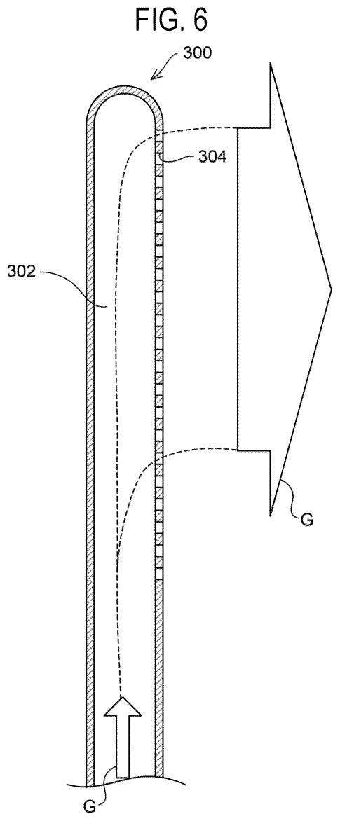

First, a nozzle 300 of a comparative example, which is not included in this aspect, is described with reference to FIG. 6. As illustrated in FIG. 6, the nozzle 300 has the same configuration as the nozzle 249a in which the modifier 276a is not provided. In the nozzle 300 in which the modifier 276a is not provided, when a flow rate of the gas flowing inside (in a flow path 302) increases, there occurs a phenomenon in which it is difficult for the gas to flow into the processing chamber 201 from an opening 304 located at an upstream side in a gas supply direction among a plurality of openings 304. In the comparative example shown in FIG. 6, it is difficult for gas to flow into the processing chamber 201 from five openings 304 from an opening 304 located at an uppermost stream in the gas supply direction among the plurality of openings 304.

Next, the nozzle 249a of this aspect is described with reference to FIGS. 5A and 5B. As illustrated in FIG. 5A, the nozzle 249a includes the modifier 276a provided in the flow path 272a. In the nozzle 249a, although a flow rate of the gas flowing in the flow path 272a increases, there occurs no phenomenon in which it is difficult for the gas to flow into the processing chamber 201 from an opening 274a located at an upstream side in the gas supply direction among the plurality of openings 274a. Specifically, by the modifier 276a provide block a portion of the flow path 272a, flow of the gas flowing in the flow path 272a is perturbed before reaching the plurality of openings 274a. That is, the flow (one laminar flow) of the gas is perturbed by the modifier 276a, so that it is possible to change the flow of the gas. In the nozzle 249a shown in FIG. 5A, the flow of the gas is divided by the modifier 276a, so that a portion of the gas flows in the flow path 272a in a state of flowing as almost laminar flow and another portion of the gas changes a direction thereof toward the opening 274a. Further, a flow rate of the gas that changes the direction thereof toward the opening 274a is changed (reduced). Accordingly, the flow of the gas into the processing chamber 201 from an opening 274a closest to the modifier 276a, i.e., an opening 274a located at an uppermost stream in the gas supply direction is improved. Thus, it is possible to evenly supply the gas into the processing chamber 201 from each of the plurality of openings 274a.

More specifically, as illustrated in FIG. 5B, in the nozzle 249a, a plurality of flows of the gas are generated by the modifier 276a. Examples of the plurality of flows of the gas may be turbulent flow, uniform flow, and eddy flow. Further, in an example of FIG. 5B, turbulent flow F2, stagnation flow F3, and eddy flow F4 were generated in addition to laminar flow. When the gas flows in the flow path 272a, flow (one laminar flow) of the gas is perturbed by the modifier 276a, so that for example, flow of a portion of the gas becomes uniform flow (laminar flow F1), flow of another portion of the gas becomes the turbulent flow F2, flow of still another portion of the gas becomes the stagnation flow F3, and flow of still another portion of the gas becomes the eddy flow F4. As for the stagnation flow F3 or the eddy flow F4, a direction of the flow of the gas has been changed, and besides, any of these flows also flows in flow path 272a similarly to the laminar flow F1 or the turbulent flow F2. FIG. 5B may also be a view obtained by taking a moment when flow (one laminar flow) of the gas has collided with (reached) the modifier 276a. That is, it is considered that a phenomenon in which the stagnation flow F3 or the eddy flow F4 is generated is one of main factors that the flow velocity of the gas is reduced. As such, as a result that a plurality of flows are generated in the gas by the modifier 276a, it is easy to supply the gas into the processing chamber 201 from the opening 274a closest to the modifier 276a. Accordingly, it is possible to evenly supply the gas into the processing chamber 201 from each opening 274a. As a result, wafer in-plane improvement of a film thickness is expected.

In addition, the term “laminar flow” in this embodiment indicates a state in which the flow of the gas is not perturbed, and is flow designated by reference numeral F1 in FIG. 5B. Further, the laminar layer may also be referred to as uniform flow.

In addition, the term “turbulent flow” in this embodiment indicates a state in which the flow of the gas is perturbed, and is flow designated by reference numeral F2 in FIG. 5B.

In addition, the term “stagnation flow” in this embodiment indicates a state in which the flow of the gas stagnates, and is flow designated by reference numeral F3 in FIG. 5B.

In addition, the term “eddy flow” in this embodiment indicates a state in which the gas flows while swirling, and is flow designated by reference numeral F4 in FIG. 5B.

In addition, in FIG. 5B, although the stagnation flow and the eddy flow have been designated by reference numerals, the stagnation flow and the eddy flow may be included in the turbulent flow in a broad sense meaning.

(4) Effects by this Aspect

According to this aspect, one or more effects described below are obtained.
(a) In the nozzle 249a, as illustrated in FIG. 5A, the flow of the gas flowing in the flow path 272a is perturbed by the modifier 276a. In other words, the flow of the gas flowing in the flow path 272a is changed by the modifier 276a. The flow of the gas is changed as described above, so that it is possible to evenly supply the gas into the processing chamber 201 from each opening 274a. Accordingly, for example, wafer in-plane improvement of a film thickness is expected.
(b) In the nozzle 249a, the flow of the gas is perturbed by the modifier 276a, so that as illustrated in FIG. 5B, a plurality of flows are generated, such as that flow of a portion of the gas becomes the laminar flow F1, that flow of another portion of the gas becomes the turbulent flow F2, that flow of still another portion of the gas becomes the stagnation flow F3, and that the flows are mixed. As such, in the nozzle 249a, the plurality of flows are generated by the modifier 276a, so that it is possible to evenly supply the gas into the processing chamber 201 from each opening 274a. Accordingly, for example, wafer in-plane improvement of a film thickness is expected.
(c) In the nozzle 249a, the flow of the gas is perturbed by the modifier 276a, so that a plurality of flows are generated, such as that flow of a portion of the gas becomes the laminar flow F1, that flow of another portion of the gas becomes the turbulent flow F2, that flow of still another portion of the gas becomes the stagnation flow F3, and that the flows are mixed. That is, flow of a portion of the gas is changed from the laminar flow by the modifier 276a. Therefore, a flow velocity of a portion of the gas is changed, and the gas reaches the opening 274a at the changed flow velocity. As a result, it is possible to evenly supply the gas into the processing chamber 201 from each opening 274a.
(d) In the nozzle 249a, the flow of the gas is perturbed by the modifier 276a, so that a plurality of flows are generated, such as that flow of a portion of the gas becomes the laminar flow F1, that flow of another portion of the gas becomes the turbulent flow F2, that flow of still another portion of the gas becomes the stagnation flow F3, and that the flows are mixed. As the flow of the gas is perturbed by the modifier 276a, the direction of flow of a portion of the gas is changed such that the gas reaches the opening 274a. As a result, it is possible to make the gas evenly flow into the processing chamber 201 from each opening 274a.

### <Modification 1>

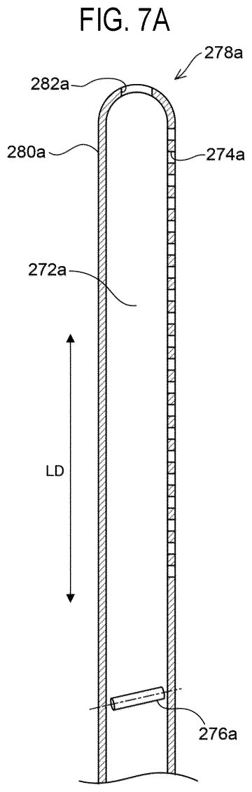

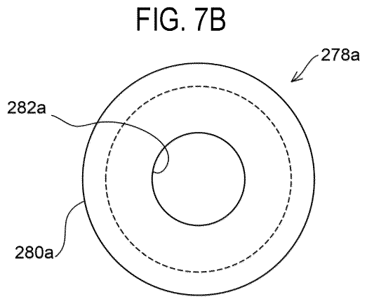

In the above-described aspect, a front end of the nozzle 249a, a front end of the straight tube portion 270a is closed, but the present disclosure is not limited to this configuration. For example, in a nozzle 278a shown in FIG. 7A, a second opening 282a (hereinafter, abbreviated as an “opening 282a”) that faces a direction along the flow path 272a may be provided at a front end of a straight tube portion 280a, i.e., a front end of the flow path 272a. Further, the nozzle 278a has the same configuration as the nozzle 249a except a configuration in which the opening 282a is provided at the front end. The opening 282a is configured to release gas except the gas supplied toward the processing chamber 201 from the opening 274a into the processing chamber 201. Further, an opening area of the opening 282a is larger than an opening area of one of a plurality of openings 282a. Further, as illustrated in FIG. 7B, a shape of the opening 282a may be at least one of a circle, an ellipse, and a polygon. In the nozzle 278a, the same effects as the above-described aspect are obtained. Further, in the nozzle 278a, since introduced gas does not stay in the flow path 272a and is released outside the flow path 272a through the opening 282a, it is possible to evenly regulate a pressure in the flow path 272a. Accordingly, like the above-described aspect, it is possible to evenly supply the gas into the processing chamber 201 from each of the plurality of openings 274a. As a result, wafer in-plane improvement of a film thickness is expected.

### <Modification 2>

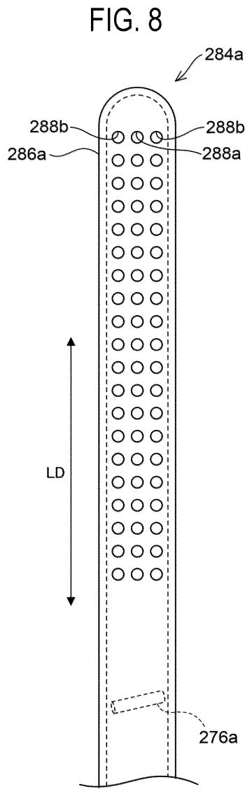

In the above-described aspect, the plurality of openings 274a are provided in a column in a straight tube portion 270a of the nozzle 249a, but the present disclosure is not limited to this configuration. For example, in a nozzle 284a shown in FIG. 8, a plurality of openings may be provided in a plurality of columns (three columns in an example of FIG. 8) in a straight tube portion 286a. Further, among the three columns, a plurality of openings constituting a central column are designated by reference numeral 288a, and a plurality of openings constituting both columns with the central column interposed therebetween are designated by reference numeral 288b. The plurality of openings 288a are an example of first gas jets, and the plurality of openings 288b are an example of second gas jets. The plurality of openings 288a and the plurality of openings 288b are configured to be able to supply the gas between a plurality of wafer planes. For example, the plurality of openings 288a are configured to be able to supply the gas toward a center side of the wafer 200 in the processing chamber 201. Further, the plurality of openings 288b is configured to be able to supply the gas toward a peripheral side of the wafer 200 in the processing chamber 201. However, the present disclosure is not limited to these openings. For example, the plurality of openings 288a and the plurality of openings 288b may be provided in a direction intersecting a length direction LD of the straight tube portion 286a as the direction in which the flow path 272a extends, the gas may be supplied toward the center side of the wafer 200 in the processing chamber 201 from each of the plurality of openings 288a and the plurality of openings 288b, and the gas may be supplied vertically to the length direction LD of the straight tube portion 286a from each of the plurality of openings 288a and the plurality of openings 288b. Further, at least one of a flow rate of the gas supplied from each of the plurality of openings 288b, a diameter of the opening 288b, and an opening area of the opening 288b may become almost the same or the same as a flow rate of the gas supplied from each of the plurality of openings 288a, a diameter of the opening 288a, and an opening area of the opening 288a. Further, in the nozzle 284a, since the gas with almost the same flow rate or the same flow rate as the plurality of openings 288a is supplied from the plurality of openings 288b, an effect that suppresses return flow of the gas supplied from the plurality of openings 288a, so that the gas supplied from each of the plurality of openings 288a and the plurality of 288b evenly flows in a wafer plane in the processing chamber 201 without generating the return flow on the wafer 200. As a result, since it is possible to evenly supply the gas supplied from the plurality of openings 288a and the plurality of openings 288b between wafer planes, wafer in-plane improvement of a film thickness is expected. Here, the term “return flow” refers to flow in which a portion of the gas jetted from the opening 288a flows in a U shape on the wafer W and returns to the peripheral side from the center side of the wafer 200.

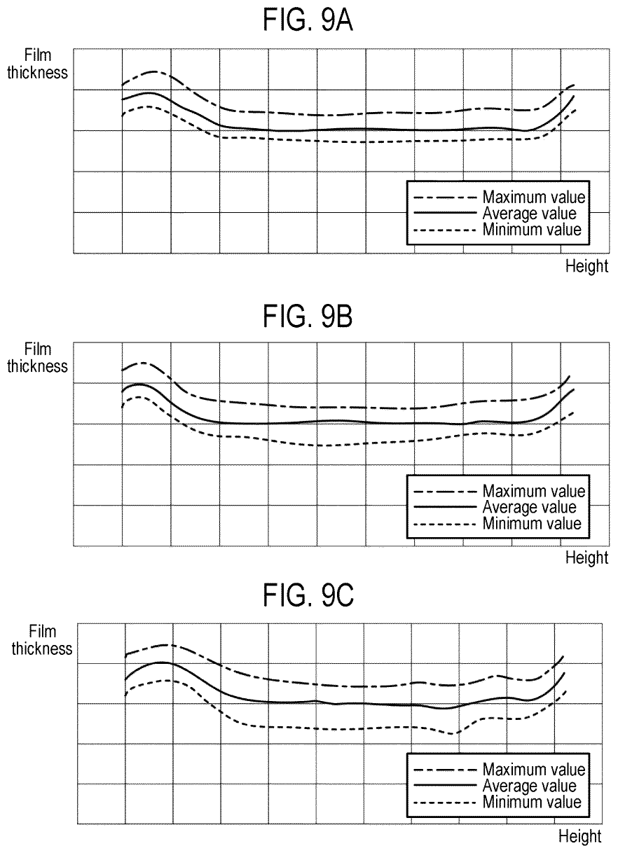

The nozzle 284a of the above-described aspect is not limited to the above-described configuration, and may have, for example, a configuration in which the opening 282a is provided at a front end of the straight tube portion 286a of the nozzle 284a. Here, results obtained by verifying effects of the present disclosure, using the nozzle 284a provided with the opening 282a, as an embodiment, are shown in FIGS. 9A to 9C. In addition, a nozzle of Embodiment 1 is an annular tube, and a shape of a plurality of openings is a circle. Further, a shape of the flow modifier 276a is a round bar of q8 mm. Meanwhile, a nozzle of Embodiment 2 is the same as the nozzle of Embodiment 1 except that a round bar has q4 mm. A nozzle of Comparative Example is the same as the nozzle of Embodiment 1 except that no round bar is provided. The vertical axis represent a film thickness, and “height” of the horizontal axis represents a position at which the wafer 200 is loaded on the boat 217. As coming closer to the right, this represents that the wafer 200 is supported at a higher position of the boat 217.

The results were such that in FIG. 9A (Embodiment 1), film thickness uniformity between the wafers 200 was 5.8%, in FIG. 9B (Embodiment 2), film thickness uniformity between the wafers 200 was 6.2%, and in FIG. 9C (Comparative Example), film thickness uniformity between the wafers 200 was 6.9%. From this, the effect that by the flow modifier 276a, the gas evenly flows between the wafers 200 was substantiated.

In addition, as a result obtained by performing comparison between FIG. 9A (Embodiment 1) and FIG. 9C (Comparative Example), in FIG. 9A (Embodiment 1), film thickness uniformity in the wafer 200 plane was 3.7% to 5.8%, and in FIG. 9C (Comparative Example), film thickness uniformity in the wafer 200 plane was 4.4% to 8.9%. Further, while in FIG. 9A (Embodiment 1), a deviation between a maximum value and a minimum value of a film thickness was 11.2%, in FIG. 9C (Comparative Example), a deviation between a maximum value and a minimum value of a film thickness was 14.1%. Further, while in FIG. 9C (Comparative Example, an average resolution in the nozzle 249a was 8.0%, in FIG. 9A (Embodiment 1), an average resolution in the nozzle 249a was 7.2%, which slight improvement was seen. From this, the effect that by the flow modifier 276a, the gas evenly flows between the wafers 200 was also substantiated.

### <Another Aspect of Present Disclosure>

In the above, the aspect of the present disclosure has been described in detail. However, the present disclosure is not limited to the above-described aspect, and can be variously modified without departing from the gist thereof. In the above-described embodiment, a configuration designated as so-called straight nozzle (also referred to as an I-shaped nozzle) has been described, but the present disclosure is not limited to this configuration. For example, a U-turn nozzle, a Y-shape nozzle, an N-shaped nozzle, and a W-shaped nozzle may also be applied to the present disclosure.

In the above-described aspect, a case where a large amount of raw material gas is supplied extremely at a time (flash supply) has been described in the step A, but for example, non-flash supply of the raw material gas may be made, i.e., the raw material gas may be supplied into the processing chamber 201 without charging the raw material gas in the storage 240a.

In addition, as the raw material gas of the above-described aspect, for example, a silane-based gas containing Si as a major element constituting a film formed on the wafer 200 may be used. As the silane-based gas, for example, a gas containing Si and halogen, i.e., a halosilane-based gas may be used. Halogen includes chlorine (Cl), fluorine (F), bromine (Br), iodine (I), and the like. As the halosilane-based gas, for example, chlorosilane gas containing Si and Cl may be used. Further, as the raw material gas, in addition to the chlorosilane gas, for example, a fluorosilane gas such as tetrafluorosilane (SiF₄) or difluorosilane (SiH₂F₂), a bromosilane gas such as tetrabromosilane (SiBr₄) gas or dibromosilane (SiH₂Br₂) gas, or an iodosilane gas such as tetraiodosilane (SiI₄) gas or diiodosilane (SiH₂I₂) may be used. As the raw material gas, one or more of these gases may be used. Further, as the raw material gas, in addition to the above gases, for example, a gas containing Si and an amino group, i.e., aminosilane gas may be used. The amino group refers to a monovalent functional group obtained by removing hydrogen (H) from ammonia, primary amine, or secondary amine, and may be represented such as —NH₂, —NHR or —NR₂. Here, R represents an alkyl group, and two Rs of —NR₂ may be the same or different from each other. Further, as the raw material gas, for example, aminosilane gas such as tetrakis(dimethylamino)silane (Si[N(CH₃)_{2]4}) gas, tris(dimethylamino)silane (Si[N(CH₃)_{2]3}H) gas, bis(diethylamino)silane (Si[N(C₂H₅)₂]₂H₂) gas, bis(tert-butylamino)silane (SiH₂[NH(C₄H₉)]₂) gas, or (diisopropylamino)silane (SiH₃[N(C₃H₇)₂]) gas may be used. As the row material gas, one or more of these gases may be used.

As the reaction gas of the above-described aspect, for example, a hydronitrogen-based gas such as ammonia (NH₃) gas, diazene (N₂H₂) gas, hydrazine (N₂H₄) gas, or N₃H₈ gas may be used. As the reaction gas, one or more of these gases may be used.

The processing apparatus of this embodiment may be applied not only to a semiconductor manufacturing apparatus but also to an apparatus for processing a glass substrate, such as an LCD apparatus. Further, the film forming processing includes, for example, CVD, PDV, a processing of forming an oxide film, a nitride film, or both thereof, a processing of forming a film including a metal, and the like. Further, a processing such as an annealing processing, an oxidization processing, a nitriding processing, a diffusion processing, and the like may also be included.

The above-described recipe is not limited to a newly created recipe, but may be prepared by, for example, changing the existing recipe already installed in the substrate processing apparatus 100. In the case of changing the recipe, the changed recipe may be installed in the substrate processing apparatus 100 via an electric communication line or a recording medium in which the recipe is recorded. Further, the existing recipe already installed in the substrate processing apparatus 100 may be directly changed by operating the input/output device 122 included in the existing processing apparatus 100.

In the above-described aspects, an example in which a film is formed using a batch-type substrate processing apparatus 100 that processes a plurality of substrates at a time has been described. The present disclosure is not limited to the above-described aspects, and can be suitably applied to a case of forming a film, using, for example, a single wafer type processing apparatus that processes one or more substrates at a time. Further, in the above-described aspects, an example in which a film is formed using the substrate processing apparatus 100 including a hot wall type of processing furnace has been described. The present disclosure is not limited to the above-described aspects, and can be suitably applied to a case of forming a film, using a substrate processing apparatus including a cold wall type processing furnace.

Even in a case where such processing apparatuses are used, each processing can be performed in accordance with processing procedures and processing conditions similar to those in the above-described aspects or modifications, so that effects similar to those in the above-described aspects or modifications can be obtained.

The above-described aspects or modifications can be used in combination as appropriate. The processing procedures and processing conditions at that time can be similar to the processing procedures and processing conditions in the above-described aspects or modifications, for example.

According to the present disclosure in some embodiments, it is possible to make gas evenly flow between substrates.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A gas supply comprising:
a flow path in which a gas flows;
a plurality of openings respectively provided in a direction intersecting the flow path to supply the gas into a processing chamber; and
a flow modifier provided to block a portion of the flow path and configured to perturb flow of the gas flowing in the flow path toward the plurality of openings.

2. The gas supply of claim 1, wherein the flow modifier is configured to generate a plurality of flows of the gas in the flow path.

3. The gas supply of claim 2, wherein the flow modifier is configured to generate turbulent flow of the gas in a vicinity of the plurality of openings.

4. The gas supply of claim 3, wherein the flow modifier is configured to cause flow of at least a portion of the gas to stagnate.

5. The gas supply of claim 3, wherein the flow modifier is configured to change flow of at least a portion of the gas from uniform flow to turbulent flow.

6. The gas supply of claim 2, wherein the flow modifier is configured to change a flow velocity of at least a portion of the gas flowing in the flow path.

7. The gas supply of claim 2, wherein the flow modifier is configured to direct flow of at least a portion of the gas toward an inner wall that constitutes the flow path and is provided with the openings therein.

8. The gas supply of claim 1, wherein the flow modifier is provided at an upstream side from the plurality of openings in a supply direction of the gas in the flow path.

9. The gas supply of claim 8, wherein the flow modifier is provided at a position that is located at a predetermined distance from an opening located at an uppermost stream side in the supply direction of the gas among the plurality of openings.

10. The gas supply of claim 1, further comprising a second opening provided at a front end of the flow path to face a direction along the flow path,
wherein the second opening is configured to release a gas that is not supplied toward a workpiece disposed in the processing chamber.

11. The gas supply of claim 10, wherein an opening area of the second opening is larger than an opening area of one of the plurality of openings.

12. The gas supply of claim 10, wherein a shape of the second opening is at least one of a circle, an ellipse, and a polygon.

13. The gas supply of claim 1, wherein a shape of the flow modifier is a rod shape, a plate shape, a spherical shape, a net shape, a honeycomb shape, or a combined shape thereof.

14. The gas supply of claim 1, wherein a shape of the openings and a cross-sectional shape of the flow modifier are at least one of a circle, an ellipse, and a polygon.

15. The gas supply of claim 1, wherein the plurality of openings include a first gas jet and a plurality of second gas jets, each of which supplies the gas toward the processing chamber, and
wherein the first gas jet and the plurality of second gas jets are configured to be able to supply the gas between substrates of a plurality of substrates disposed at predetermined intervals in the processing chamber.

16. The gas supply of claim 15, wherein the first gas jet is configured to be able to supply the gas toward a substrate center side of the processing chamber, and the plurality of second gas jets are configured to be able to supply the gas toward a substrate peripheral side of the processing chamber.

17. The gas supply of claim 15, wherein the first gas jet is configured such that at least one of following conditions is satisfied:
a flow rate of the gas supplied from the first gas jet is substantially the same as or identical to a flow rate of the gas supplied from each of the plurality of second gas jets;
a diameter of the first gas jet is substantially the same as or identical to a diameter of each of the plurality of second gas jet; and
an opening area of the first gas jet is substantially the same as or identical to an opening area of each of the plurality of second gas jet.

18. A processing apparatus comprising a gas supply which includes:
a flow path in which a gas flows;
a plurality of openings respectively provided in a direction intersecting the flow path to supply the gas into a processing chamber; and
a flow modifier provided to block a portion of the flow path, to be configured to perturb flow of the gas flowing in the flow path toward the plurality of openings.

19. A gas supply method, in which a gas is supplied by a gas supply including:
a flow path in which a gas flows;
a plurality of openings respectively provided in a direction intersecting the flow path to supply the gas into a processing chamber; and
a flow modifier provided to block a portion of the flow path, to be configured to perturb flow of the gas flowing in the flow path toward the plurality of openings.

20. A method of manufacturing a semiconductor device, comprising processing a workpiece disposed in a processing chamber by supplying a gas into the processing chamber by the gas supply method of claim 19.
